(19) United States
(12) Patent Application Publication
(10) Pub. No.: US 2002/0177307 A1
(43) Pub. Date: Nov. 28, 2002

(54) Semiconductor device and a method for forming a via hole in a semiconductor device

(76) Inventor: Kazuyoshi Ueno, Tokyo (JP)

Correspondence Address: KATTEN MUCHIN ZAVIS ROSENMAN, 575 MADISON AVENUE, NEW YORK, NY, 10022-2585, US

(21) Appl. No.: 09/490,705

(22) Filed: Jan. 24, 2000

(30) Foreign Application Priority Data
Jan. 25, 1999 (JP) 16258/1999

(51) Int. Cl. H01L 21/44; H01L 23/48; H01L 23/52; H01L 29/40

(52) U.S. Cl. 438/687

(57) ABSTRACT

In a method for forming a via hole of a semiconductor device, a first step via hole is formed in a SiO₂ layer/etching-step layer/Cu layer laminate, this formation being stopped at the etching-stop layer, after which resist is peeled away, and a second step via hole continuous with the first step via hole is formed in the etching-stop layer. These via holes are patterned and a barrier film is formed thereonto using sputtering. By shortening the overetching time an increase in the electrical resistance of the Cu-Cu connection is suppressed, and current leakage is prevented.

### BACKGROUND OF THE INVENTION

1. Field of the Invention

The present invention relates to a semiconductor device and a method for forming a via hole in a semiconductor device, and more particularly to a semiconductor device and a method for forming a via hole, whereby a via hole is formed so as to extend to a copper interconnect layer without being adversely affected by the copper.

2. Background of the Invention

The achievement of high levels of integration and smaller feature sizes in semiconductor devices creates a demand for reduction in the diameter of via holes that are used to make connections among a plurality of interconnect layers to have a very small diameter.

That this reduction in diameter leads to an increase in electrical resistance, has been reported in the literature (S. Lakashminarayanam et al, Proc. 1994 VMIC (1994), p. 49).

Additionally, it is known that a via leakage current flows among a plurality of via holes.

It is obvious that this via leakage current occurs because, when a via hole is formed, the copper of a copper interconnect layer that is exposed becomes reattached to the via hole surface when sputtering is done using argon, and it can be easily inferred that, if the copper is diffused, there is a further increase in the leakage current.

This problem with the prior art method is illustrated in more detail in FIG. 2(a), FIG. 2(b), and FIG. 2(c). As shown in FIG. 2(a), a resist layer/SiO₂ layer/Cu interconnect layer are formed at a first step, and a via hole extending to the copper interconnect layer is formed at the second step.

As shown in FIG. 2(b), resist is removed at a third step.

At this step, copper on the surface of the copper interconnect layer acts on the via hole side surface so as to form a copper deposition on the side surface, this side surface copper deposition being a cause of leakage current.

In addition, there is oxidation of the copper surface of the copper interconnect layer, this oxidation leading to an increase in electrical resistance. The barrier performance of the TaN barrier film formed as shown in FIG. 2(c) is weak in the barrier characteristic.

When making connection between a plurality of interconnects by filling contact holes formed so as to extend to a copper interconnect layer with copper, a method of avoiding an insufficient Cu-Cu electrical connection is known from the disclosure in the Japanese Unexamined Patent Publication (KOKAI) No. 10-261715.

Even if the Cu-Cu connection is good, there is no solution for the above-noted problem of re-attachment of copper.

In a proposed method to solve this type of problem than can be considered, a substrate having a SiO₂/SiN/Cu three-layer structure is formed, a first step via hole being formed so that its formation is stopped at the middle layer of SiN, after which a second step via hole is formed to shorten the overetching time, thereby avoiding the adverse effect of the copper.

In this proposal, there is a step of forming via holes that are similar in appearance, this being shown in FIG. 5(c) of the above-noted Japanese Unexamined Patent Publication (KOKAI) No. 10-261715.

The above-noted known method of forming a via hole, does not provide neither sufficient suppression of the oxidation of the copper surface, nor sufficient solution for the problem of re-attachment of copper that occurs when cleaning is done when argon plasma after formation of the via hole.

Additionally, when depositing a barrier film by sputtering, in the method of the past, the above-noted problems occur, making it difficult to avoid the adverse effect of the copper.

By avoiding a lengthening of the overetching time of the via hole (particularly Dual Damascene), by avoiding oxidation contamination of the copper surface during peeling using oxygen plasma or the like, and by avoiding the diffusion and re-attachment of copper to side surfaces of the via hole when sputtering is done using argon or the like, it is possible to eliminate an increase in electrical resistance while suppressing the occurrence of leakage current.

Accordingly, it is an object of the present invention to provide a method for forming a via hole in a semiconductor device, whereby by avoiding a lengthening of the overetching time of the via hole it is possible to not only eliminate an increase in electrical resistance, but also suppress the occurrence of leakage current.

It is a further object of the present invention to provide a method for forming a via hole of a semiconductor device whereby by avoiding a lengthening of the overetching time of the via hole and also by avoiding oxidation contamination of the exposed copper surface, an increase in electrical resistance is effectively suppressed, as is the occurrence of leakage current.

It is yet another object of the present invention to provide a method for forming a via hole in a semiconductor device, whereby by avoiding a lengthening of the overetching time of the via hole, by avoiding oxidation contamination of the exposed copper surface, and by avoiding the influence of copper when performing sputtering, it is possible to more effectively suppress an increase in electrical resistance and to more effectively suppress the occurrence of leakage current.

Further object of the present invention is to provide a semiconductor device which has at least one via hole filled with an electrical conductive material so as to eliminate an increase in electrical resistance as well as to suppress the occurrence of leakage current.

### SUMMARY OF THE INVENTION

In order to achieve the above-noted objects, the present invention has the following basic technical constitution. In the description of that constitution which follows, numbers in parentheses minimally indicate a number of a plurality of claims of the accompanying claims that correspond with various technical aspects of the present invention, although it will be understood that these numbers are provided to indicate this correspondence, and do not restrict the scope of the claimed invention to the embodiments.

A first aspect of the present invention is a semiconductor device which comprises, a substrate, on a main surface of which, interconnect layers made at least of copper are formed along with a predetermined pattern in buried condition, an etching-stop layer formed on the main surface of the substrate, and an insulation layer formed on the etching-stop layer, and wherein the semiconductor device further comprises a via-hole provided on a main surfacer of the insulation layer and penetrating through the insulation layer and the etching-stop layer so that a bottom of the via-hole reaches at a surface of the interconnect layer, and wherein a barrier layer continuously covering the main surface of the insulation layer, inside wall surface of the via-hole and surface of the interconnect layer integratedly.

On the other hand, a second aspect of the present invention is a method for forming a via hole of a semiconductor device comprising, a step of forming a first step via hole in a laminated structure formed by a copper layer, an etching-stop layer formed on a surface of the copper layer, and an insulation layer formed on a surface of the etching-stop layer, thereby a bottom of the first step via hole is stopped at the etching-stop layer, a step of forming a second step via hole continuous with the first step via hole in the etching-stop layer, thereby a bottom of the second step via hole reaching at a surface of the interconnect layer, a step of cleaning the second step via hole, and a step, after the cleaning, of forming a barrier film on the first and second step via holes, by sputtering.

### BRIEF DESCRIPTION OF THE DRAWINGS

FIG. 1(a), FIG. 1(b), and FIG. 1(c) are cross-section views showing the steps of an embodiment of a method of forming a via hole according to the present invention.

FIG. 2(a), FIG. 2(b), and FIG. 2(c) are cross-section views showing the steps of a prior art method.

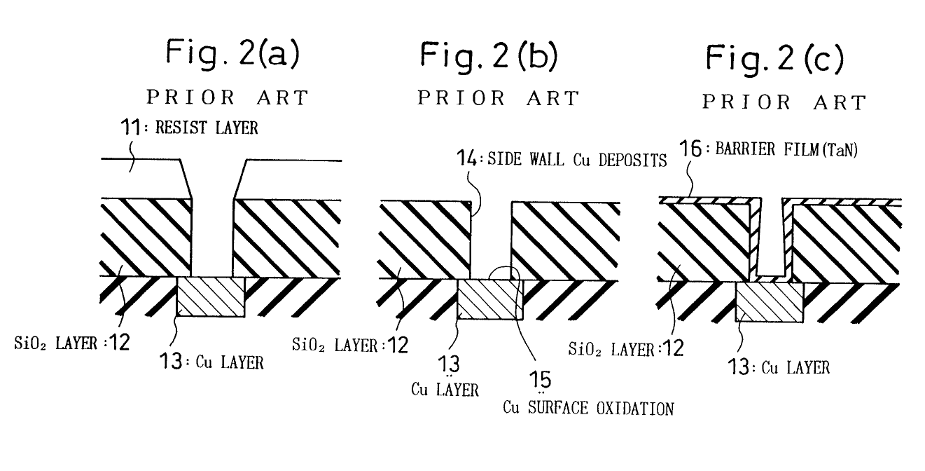

### DESCRIPTION OF THE PREFERRED EMBODIMENTS

Preferred embodiments of a semiconductor device and a method for forming a via hole in a semiconductor device according to the present invention will be explained in detail below, with references being made to relevant accompanying drawings.

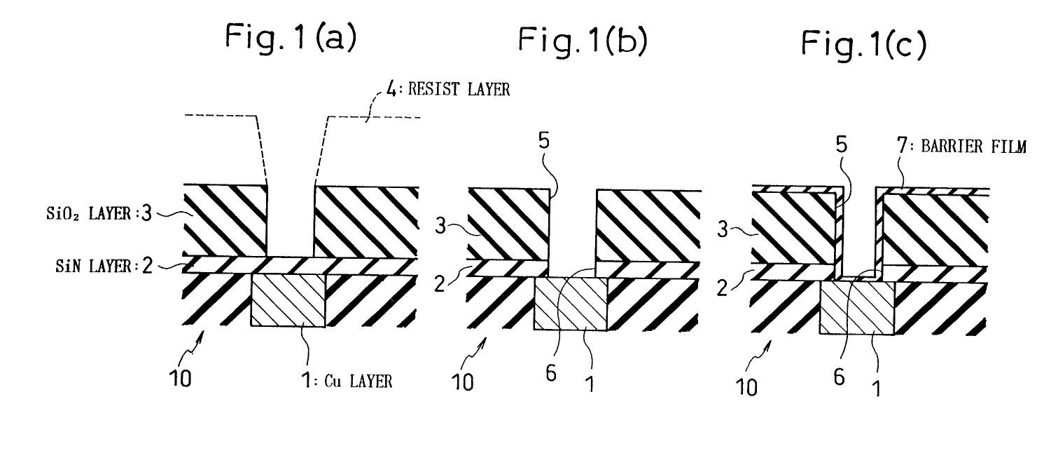

In FIG. 1(c) shows a specific embodiment of the semiconductor device 30 according to the present invention and in that a semiconductor device 30 which comprises, a substrate 10, on a main surface of which, interconnect layers 1 made at least of copper are formed along with a predetermined pattern in buried condition, an etching-stop layer 2 formed on the main surface of the substrate 10, and an insulation layer 3 formed on the etching-stop layer 2, and wherein the semiconductor device 30 further comprises a via-hole 20 provided on a main surfacer of the insulation layer 3 and penetrating through the insulation layer 3 and the etching-stop layer 2 so that a bottom 21 of the via-hole 20 reaches at a surface of the interconnect layer 1, and wherein a barrier layer 7 continuously covering the main surface of the insulation layer 3, inside wall surface 5 of the via-hole 20 and surface of the interconnect layer, integratedly, is shown.

Since the semiconductor device 30 of the present invention has such a configuration as mentioned above, it can have features in that it has a low via hole resistance and improved reliability as well as anti-leakage current would be caused between via holes.

On the other hand, one embodiment of a method for forming a via hole in a semiconductor device having such a configuration as mentioned above, in the present invention will be explained hereunder with reference to attached FIGS. 1(a) to 1(c).

The basic method for producing the via hole 20 in a semiconductor device 30 of the present invention, comprising, a step of forming a first step via hole (5) in a laminated structure formed by a copper layer (1), an etching-stop layer (2) on the surface side of the copper layer (1), and a insulation layer (3) on the surface side of the etching-stop layer (2), a step whereby the formation of the first step via hole (5) is stopped by the etching-stop layer (2), and a second step via hole (6) is further formed so as to continue from the first step via hole (5), thereby forming a via hole, a step whereby the second step via hole (6) extends to the copper layer (1) and the second step via hole (6) is cleaned, and a step, after the above-noted cleaning, whereby a barrier film (7) is formed on the first step via hole (5) and the second step via hole (6) by sputtering.

The formation of this two-stepped via hole, affects the above-mentioned cleaning step and the above-mentioned sputtering step and due to such shortened overetching time, it is possible to minimize the influence of the copper on the steps of cleaning and sputtering.

Further, because the sputtering is done after cleaning, it is possible to minimum the current leakage.

On the other hand, it is possible to effectively suppress an increase in the electrical resistance of a Cu-Cu connection made in this manner by filling a via hole with copper after sputtering.

In the present invention, it is preferable that the resist layer (4) be peeled away after forming the first step via hole (5) but before forming the second via hole (6).

It is particularly preferable that the step for cleaning the via hole (5, 6) be performed at a low oxygen partial pressure. It is additionally preferable that the step for cleaning the via hole has a step for treating the via hole with an oxygen plasma before a step for annealing same at a low oxygen partial pressure.

It is preferable that the step for cleaning the via hole further has a step for wet processing of the via hole after a step for treating the via hole with an oxygen plasma.

It is further preferable that the step for annealing same at a low oxygen partial pressure be performed in a chamber for sputtering.

It is desirable that the step for annealing at a low oxygen partial pressure be performed just before such sputtering process will be performed.

It is extremely effective to leave the semiconductor substrate to be treated in the step for annealing at a low oxygen partial pressure, in a sputtering chamber at a temperature of 250° C. or higher for 3 minutes or longer before forming the barrier film.

The low oxygen partial pressure is 1 Torr or lower.

It is particularly effective for the formation of the two-step via hole if the step for annealing at a low oxygen partial pressure is performed in a hydrogen atmosphere, and particularly in an atmosphere in which hydrogen radicals are supplied.

A more specific embodiment of the semiconductor device and a method for producing a via hole in the semiconductor device will be further explained hereunder.

As shown in FIG. 1(a), a substrate 10 is prepared as a 3-layer structure. This 3-layer substrate is formed by a copper interconnect layer 1 on a main surface of and in the substrate 10, a SiN layer 2 formed over on the upper surface of the copper interconnect layer 1, and a SiO₂ layer 3 formed on the upper surface of the SiN layer 2.

A resist layer 4 is formed and then patterned, so as to form a first step via hole 5. The first step via hole 5 extends to the surface of the SiN layer 2, but is stopped at that surface by the etching.

The surface of the copper interconnect layer 1, not being covered by the SiN layer 2, and thus is not exposed.

Next, as shown in FIG. 1(b), the resist layer 4 is removed by a step such as ashing. Then, as shown in FIG. 1(b), a second via hole 6 is formed in the SiN layer 2, continuous with the first step via hole 5.

The second step via hole 6 extends to the surface of the copper interconnect layer 1. At this stage, the surface of the copper interconnect layer 1 is exposed.

After forming a via hole made up of the first step via hole 5 and the second step via hole 6, a three-step cleaning process is performed.

The first cleaning step is done with an oxygen plasma. The second cleaning step is done as wet processing, using DHF or the like.

The third cleaning step is performed as annealing.

These three process steps are each performed using the customary technologies, and are performed without exposure to the outside atmosphere.

The annealing processing is performed with a low oxygen partial pressure. When annealing is done, the substrate 10 is placed in a sputtering chamber (not shown in the drawing) that is used in the next step.

The substrate 10 is place in the sputtering chamber in an atmosphere set to a temperature of 250° C., so that the substrate 10 reaches the temperature of 250° C. It is preferable that the substrate 10 be kept at 250° C. for at least 3 minutes.

Just after this time has elapsed, sputtering is performed within the chamber.

The partial pressure of oxygen in the chamber is 1 Torr or lower, and it is possible to either draw a vacuum in the chamber or introduce an argon atmosphere thereinto. As shown in FIG. 1(c), this sputtering forms a barrier film 7 on the via holes 5 and 6.

It is preferable that the above-noted low oxygen partial pressure annealing be performed in a hydrogen atmosphere.

Annealing in a hydrogen atmosphere is advantageous because it has the effect of removing an oxide film and enables quick processing at a low temperature.

It is further preferable that this low oxygen partial pressure annealing be performed while supplying hydrogen radicals.

Annealing in a hydrogen atmosphere while supplying hydrogen radicals is advantageous because it provides even better removal of an oxide film and enables quicker and lower-temperature processing.

A method for forming a via hole according to the present invention makes use of a two-step etching process, thereby preventing oxidation of the copper surface during the peeling process, preventing a deterioration of the copper surface at the bottom surface of the via hole, which results in a decrease in via hole resistance and improved reliability.

An additional effect is a shortening of the overetching time at the second etching step, and a reduced amount of plasma damage to the copper surface. Yet another effect is the ability to prevent leakage between via holes.

Another effect of the present invention is that, by performing annealing at a low oxygen partial pressure, it is possible to effectively remove an oxide layer from the copper surface. Another advantage of the present invention is the simplicity of the step at which low oxygen partial pressure annealing is performed immediately before deposition in a high-temperature sputtering chamber.

Additionally, by not using an organic gas when cleaning, there is little attachment of carbon and the like, enabling removal of a clean copper oxide film, and by not using a plasma, there is no re-attachment of copper.

What is claimed is:

1. A semiconductor device which comprises;
a substrate, on a main surface of which, interconnect layers made at least of copper are formed along with a predetermined pattern in buried condition;
an etching-stop layer formed on said main surface of said substrate; and
an insulation layer formed on said etching-stop layer,
said semiconductor device further comprises a via-hole provided on a main surfacer of said insulation layer and penetrating through said insulation layer and said etching-stop layer so that a bottom of said via-hole reaches at a surface of said interconnect layer, and wherein a barrier layer continuously covering said main surface of said insulation layer, inside wall surface of said via-hole and surface of said interconnect layer integratedly.

2. A method for forming a via hole of a semiconductor device comprising:
a step of forming a first step via hole in a laminated structure formed by a copper layer, an etching-stop layer formed on a surface of said copper layer, and an insulation layer formed on a surface of said etching-stop layer, thereby a bottom of said first step via hole is stopped at said etching-stop layer;
a step of forming a second step via hole continuous with said first step via hole in said etching-stop layer, thereby a bottom of said second step via hole reaching at a surface of said interconnect layer;
a step of cleaning said second step via hole; and
a step, after said cleaning, of forming a barrier film on said first and second step via holes, by sputtering.

3. A method for forming a via hole of a semiconductor device according to claim2, wherein said step of cleaning said via hole comprises a step for annealing said via hole at a low oxygen partial pressure.

4. A method for forming a via hole of a semiconductor device according to claim 3, wherein said step of cleaning said via hole further comprises a step for treating said via hole with an oxygen plasma, before said step of annealing said via hole at a low oxygen partial pressure.

5. A method for forming a via hole of a semiconductor device according to claim 4, wherein said step of cleaning said via hole further comprises a step for performing wet processing of the via hole after treating said via hole with an oxygen plasma.

6. A method for forming a via hole of a semiconductor device according to claim 3, wherein said step of annealing said via hole at a low oxygen partial pressure is further performed in a sputtering chamber for said sputtering.

7. A method for forming a via hole of a semiconductor device according to claim 6, wherein said step for annealing said via hole at a low oxygen partial pressure is further performed immediately before said sputtering.

8. A method for forming a via hole of a semiconductor device according to claim 7, wherein said semiconductor substrate in the step for annealing said via hole at a low oxygen partial pressure is held in said sputtering chamber at a temperature of 250° C. or greater for at least three minutes before said step of forming a barrier film.

9. A method for forming a via hole of a semiconductor device according to claim 8, wherein the oxygen partial pressure when said sputtering is performed is 1 Torr or lower.

10. A method for forming a via hole of a semiconductor device according to claim 8, wherein said step of annealing said via hole at a low oxygen partial pressure is performed in a hydrogen atmosphere.

11. A method for forming a via hole of a semiconductor device according to claim 10, wherein said step of annealing said via hole at a low oxygen partial pressure is performed in an atmosphere in which hydrogen radicals are supplied.
